(19) United States
(12) Patent Application Publication
(10) Pub. No.: US 2026/0096237 A1
(43) Pub. Date: Apr. 2, 2026

(54) TORIC-MICROLENS IMAGE SENSOR

(71) Applicant: OmniVision Technologies, Inc., Santa Clara, CA (US)

(72) Inventors: Yen-Yun WANG, San Jose, CA (US); Chen-Wei LU, Zhubei City (TW); Chao NIU, Santa Clara, CA (US)

(21) Appl. No.: 18/905,033

(22) Filed: Oct. 2, 2024

(51) Int. Cl. H01L 27/146

(52) U.S. Cl. CPC H10F 39/8063; H10F 39/182; H10F 39/8053

(57) ABSTRACT

An image sensor includes a semiconductor substrate and a toric microlens. The semiconductor substrate includes a pixel array having a plurality of rows of pixels and a plurality of columns of pixels. A pixel cell of the pixel array includes one or more pixels of the pixel array. The toric microlens is disposed on the semiconductor substrate and directly above a corresponding pixel cell of the pixel array.

### BACKGROUND

Many digital cameras have autofocusing capability. Autofocus may be fully automatic such that the camera identifies objects in the scene and focuses on the identified objects. In some cases, the camera may decide which objects are more important than other objects and subsequently focus on the more important objects. Alternatively, autofocus may utilize user input specifying which portion or portions of the scene are of interest. Based thereupon, the autofocus function identifies objects within the portion(s) of the scene, specified by the user, and focuses the camera on such objects.

One type of autofocusing method is contrast autofocus, wherein the camera adjusts the imaging objective to maximize contrast in at least a region of the scene, thus bringing that region of the scene into focus. More recently, phase-detection autofocus (PDAF) has gained popularity because it is faster than contrast autofocus. Phase-detection autofocus directly measures the degree of misfocus by comparing light passing through one portion of the imaging objective, e.g., the left portion, with light passing through another portion of the imaging objective, e.g., the right portion. Some digital single-lens reflex cameras include a dedicated phase-detection sensor in addition to the image sensor that captures images.

However, this solution is not feasible for more compact and/or less expensive cameras. Therefore, camera manufacturers are developing image sensors with on-chip phase detection. Such image sensors, “PDAF image sensors” herein, have integrated phase detection capability via the inclusion of so-called PDAF pixels in the image sensor's pixel array. The response of such PDAF pixels depends in part on the direction of illumination incident on the pixel after transmission through the imaging objective.

### SUMMARY OF THE EMBODIMENTS

Typically, PDAF image sensors include spherical microlenses, each of which is aligned above multiple pixels of the pixel array. A pixel cell of the pixel array includes a two-by-two sub-subarray of pixels, each of which has a light-sensing region that includes a photodiode. Phase detection (PD) selectivity and quad phase detection (QPD) sensitivity imbalance is a trade-off in the use of spherical-shaped of microlens in pixel array. The microlens forms a focused spot on the pixel cell, such that the focused spot illuminates a light-sensing region of one or more of the pixels.

In some PDAF image sensors, when a region of a scene is in focus, the focused spot imaged from this region is centered on the pixel cell such that each pixel of the pixel cell generates signal of substantially equal magnitude. The focused spot has a horizontal focus width Dₓ.

When the region is out of focus, the spot is decentered from the center of the pixel cell by an offset distance Δx. The value Δx/Dₓ is a measure of PD selectivity. Hence, as width Dₓ decreases, PD selectivity increases for a given offset distance Δx. Increased PD selectivity enables faster autofocus operation. However, a smaller focused spot increases variation of pixel sensitivity for pixels aligned under the same type of color filter, which results in less full well capacity.

Embodiments disclosed herein overcome this tradeoff by employing non-spherical microlenses for PDAF pixels included in an image sensor.

In a first aspect, an image sensor includes a semiconductor substrate and a toric microlens. The semiconductor substrate includes a pixel array having a plurality of rows of pixels and a plurality of columns of pixels. A pixel cell of the pixel array includes a two-by-two sub-array of pixels of the pixel array. The toric microlens is disposed on the semiconductor substrate and directly above a corresponding pixel cell of the pixel array.

In a second aspect, an image sensor includes a semiconductor substrate and a plurality of toric microlenses. The semiconductor substrate includes a pixel array having a plurality pixel cells arranged into a plurality of rows and a plurality of columns. A pixel cell of the pixel array includes a two-by-two sub-array of pixels of the pixel array. The plurality of toric microlenses is disposed on the semiconductor substrate and arranged into a plurality of microlens rows and a plurality of microlens columns. Each toric microlens is directly above a corresponding pixel cell of the pixel array. Each toric microlens has a horizontal width and a vertical width that differs from the horizontal width, such that a horizontal separation between adjacent microlens rows differs from a vertical separation between adjacent microlens columns. The horizontal width is in a direction parallel to each of the plurality of rows. The vertical width is in a direction parallel to each of the plurality of columns.

### BRIEF DESCRIPTION OF THE FIGURES

FIG. 1 illustrates an image sensor and a pixel array thereof in an exemplary use scenario.

FIG. 2 is a functional block diagram of a toric-microlens image sensor, which is an example of the image sensor of FIG. 1.

FIGS. 3A, 3B, 4A, 4B, 5A, and 5B are respective partial cross-sectional schematics of a toric-microlens image sensor, which is an example of the image sensor of FIG. 2.

FIG. 6 is a plan view of a two-by-two array pixel cells included in toric-microlens-based image sensor of FIGS. 3-5, in embodiments.

FIG. 7 is a plan view of a two-by-two array of pixel cells that form a supercell; each of the pixel cells is an example of a pixel cell of the image sensor of FIG. 2.

FIG. 8 is a plan view of an array of supercells of FIG. 7, which forms an embodiment of the pixel array of the image sensor of FIG. 2.

### DETAILED DESCRIPTION OF THE EMBODIMENTS

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

It should be appreciated that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the terms “below” and “under” may encompass both an orientation of above and below. The device may be otherwise oriented (rotated ninety degrees or at other orientations) and the spatially relative descriptors used herein interpreted accordingly. In addition, it will also be understood that when a layer is referred to as being “between” two layers, it may be the only layer between the two layers, or one or more intervening layers may also be present.

Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

As used herein, expressions like “same,” “identical”, “substantially the same”, “substantially identical”, “substantially equal” when used in reference to the dimensions of two corresponding features is to indicate the dimensions of the two features are intended to be exactly the same but may have some variability within reasonable tolerances associated with the inherent imperfections of the manufacturing processes involved to produce the corresponding features.

The term semiconductor substrate may refer to substrates formed of one or more semiconductors such as silicon, silicon-germanium, germanium, gallium arsenide, any other semiconductor materials known to those of skill in the art, combinations thereof, or a bulk substrate thereof. The term semiconductor substrate may also refer to a substrate, a slab, or a material layer formed of one or more semiconductors, subjected to previous process steps that form regions and/or junctions in the substrate.

It is further appreciated that the term “semiconductor substrate” throughout the disclosure may correspond to a part of or an entirety of a semiconductor wafer (e.g., formed of one or more of the semiconductor materials). A semiconductor substrate may also include various features, such as doped and undoped semiconductors, epitaxial layers of silicon, and other semiconductor structures formed upon the substrate. It should be noted that element names and symbols may be used interchangeably through this document (e.g., Si vs. silicon); both have identical meanings.

As used herein, the term “light” can refer to electromagnetic radiation in the ultraviolet, visible, near infrared and infrared spectra. The terms can further more broadly include electromagnetic radiation such as radio waves, microwaves, x-rays, and gamma rays. Thus, the term “light” is not limited to electromagnetic radiation in the visible spectrum. Many examples of light described herein refer specifically to electromagnetic radiation in the visible and infrared (and/or near infrared) spectra. For purposes of this disclosure, visible range wavelengths are considered to be from approximately 350 nm to 800 nm and non-visible wavelengths are considered to be longer than about 800 nm or shorter than about 350 nm. Furthermore, the infrared spectrum is considered to include a near infrared portion of the spectrum including wavelengths of approximately 800 to 1100 nm, a short wave infrared portion of the spectrum including wavelengths of approximately 1100 nm to 3 micrometers, and a mid-to-long wavelength infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

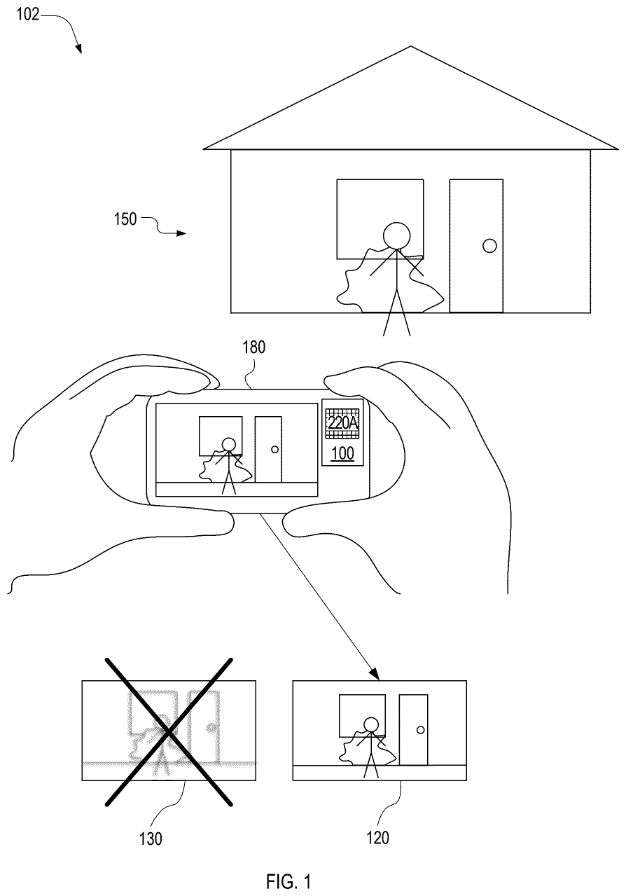

FIG. 1 illustrates an image sensor 100 with PDAF pixels in an exemplary use scenario 102. Image sensor 100 is implemented in a camera 180 for imaging a scene 150. Camera 180 may be a standalone camera, or may be a camera module integrated into a device, such as a mobile device, a computer, a security device, wearable device, head-mounted device, or a motor vehicle. Camera 180 utilizes on-chip phase detection capability of image sensor 100 to focus on scene 150. When focused, camera 180 utilizes image sensor 100 to capture a focused image 120, instead of a defocused image 130, of scene 150.

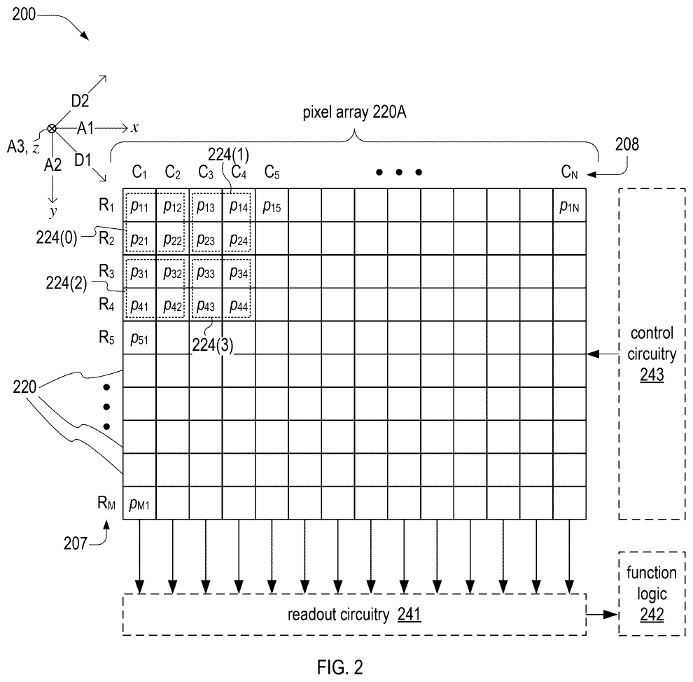

FIG. 2 is a functional block diagram of an image sensor 200. Image sensor 200 is an example of image sensor 100. The cross-section illustrated in FIG. 2 is parallel to a plane formed by orthogonal axes A1 and A2, each of which is orthogonal to an axis A3. Herein, the x-y plane is formed by orthogonal axes A1 and A2. Unless otherwise specified, an object's thickness and/or depth refers to the object's extent along axis A3. Herein, a reference to an axis x, y, or z refers to axes A1, A2, and A3, respectively. Also herein, horizontal dimensions, and vertical dimensions, such as length and width, are along directions parallel to axis A1 and axis A2, respectively. A depth dimension is in a direction parallel to axis A3.

Also herein, a horizontal plane is parallel to the x-y plane, width refers to an object's extent along the x or y axis, and a vertical axis is along the z axis. FIG. 2 also denotes a diagonal axes D1 and D2, each of which may be oriented at 45° with respect to each of axes A1 and A2.

Image sensor 200 includes two-dimensional array of pixels 220 that form a pixel array 220A configured to acquire image data for an external scene. Pixel array 220A has M rows 207(1-M) and N columns 208(1-N), where are denoted in FIG. 2 as rows R₁, R₂, . . . , R_{M} and columns C₁, C₂, . . . , C_{N}, respectively. In some embodiments, pixel array 220A may be wider along axis A1 than along axis A2, which may result from N exceeding M. Pixel array 220A may wider along axis A2 than along axis A1, which may result from M exceeding N.

Each pixel 220 is denoted as pₘₙ, where indices m and n of pixel coordinate (m,n) denote, respectively, the corresponding row and column of the pixel within pixel array 210. Pixel array 220A includes a plurality of pixel cells 224. Each pixel cell 224 may include a two-by-two sub-array of pixels 220. For example, FIG. 2 denotes pixel cells 224(0), 224(1), 224(2), and 224(3). Pixel cells 224(1), 224(2), and 224(3) are respectively horizontally adjacent, vertically adjacent, and diagonally adjacent to the pixel cell 224(0). Pixel cell 224(0) includes pixels p₁₁, p₁₂, p₂₁, and p₂₂. Pixel cell 224(1) includes pixels p₁₃, p₁₄, p₂₃, and p₂₄. Pixel cell 224(2) includes pixels p₃₁, p₃₂, p₄₁, and p₄₂. Pixel cell 224(3) includes pixels p₃₃, p₃₄, p₄₃, and p₄₄. A pixel cell 224 may occupy two adjacent rows 207 and two adjacent columns 208 of pixel array 220A. In some embodiments, each individual pixel cell 224 may be disposed under a common type of color filter and under a same microlens. In the same or different embodiments, each individual pixel cell 224 may be referred as quad phase detection pixel or QPD pixel.

In embodiments in which each pixel cell is disposed under a same microlens, image sensor 200 may include a plurality of microlenses. The plurality of microlenses may be disposed on a semiconductor substrate that includes pixel array 220A. The plurality of microlenses may be arranged into a plurality of microlens rows and a plurality of microlens columns in correspondence to the arrangement of the plurality of pixel cells 224.

Image sensor 200 may also include at least one of readout circuitry 241, function logic 242, and control circuitry 243. After each pixel 220 has acquired its image charge, the image charge is read out by readout circuitry 241 through column bitlines and transferred to function logic 242. Image sensor 200 may further include control circuitry 243 coupled with pixel array 220A for generating various signals to control operation of each pixel 220.

In the various examples, readout circuit 241 may include an analog-to-digital conversion (ADC) circuit and image buffer. The ADC circuit is coupled to convert the analog image signals received from the pixel 220 through column bitlines to digital image signals, which may be then transferred to function logic 242. Function logic 242 may simply store the image data or even manipulate the image data by applying post image processing or effects. Such image processing may, for example, include image processing, image filtering, image extraction and manipulation, determination of light intensity, crop, rotate, remove red eye, adjust brightness, adjust contrast, etc. The function logic 242 can be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic.

Control circuitry 243 may generate transfer gate signals and other control signals to control the transfer and readout of image data from all of the pixels 220 of pixel array 220A. In addition, control circuitry 243 may generate a shutter signal for controlling image acquisition. In one example, the shutter signal is a rolling shutter signal such that each row of the pixel array 220A is read out sequentially row by row during consecutive acquisition windows. The shutter signal may also establish an exposure time, which is the length of time that the shutter remains open. In one embodiment, the exposure time is set to be the same for each of the frames.

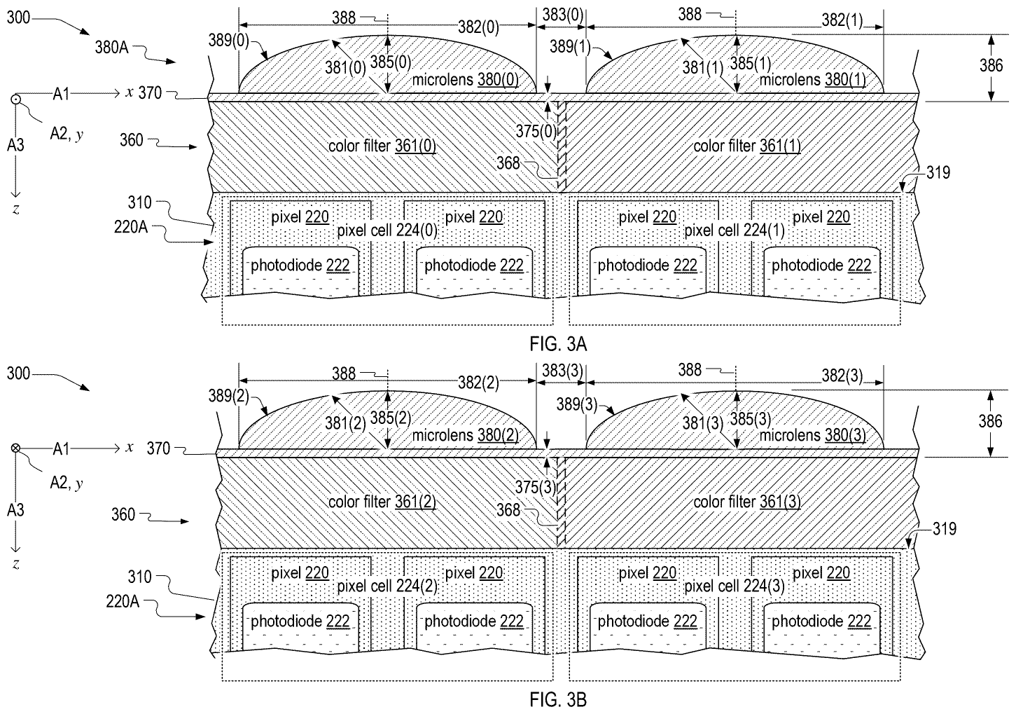

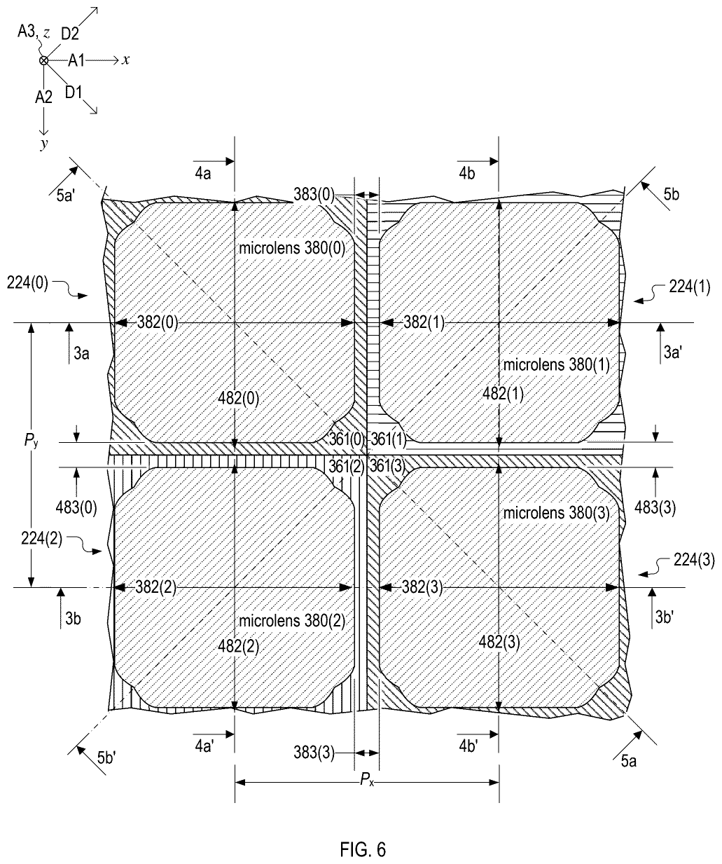

FIGS. 3A, 3B, 4A, 4B, 5A, and 5B are respective cross-sectional schematics of an image sensor 300 employing toric-microlenses, shown in plan view in FIG. 6, and taken along respective lines 3a-3a′, 3b-b, 4a-4a′, 4b-4b′, 5a-5a′, and 5b-5b′ of FIG. 6. Toric-microlens image sensor 300, hereinafter image sensor 300, is an example of image sensor 200, FIG. 2.

Cross-sectional planes 3a-3a′ and 3b-3b′ are parallel to the A1-A3 plane; cross-sectional planes 4a-4a′ and 4b-4b′ are parallel to the A2-A3 plane; and cross-sectional planes 5a-5a′ and 5b-5b′ are parallel to the A3-D1 plane e.g., along a diagonal direction of the pixel. For sake of brevity, “cross-sectional planes 3-3′” refers to both cross-sectional planes 3a-3a′ and 3b-3b′; “cross-sectional planes 4-4” refers to both cross-sectional planes 4a-4a′ and 4b-4b′; and “cross-sectional planes 5-5” refers to both cross-sectional planes 5a-5a′ and 5b-5b′. FIGS. 3-6 are best viewed together in the following description.

Image sensor 300 includes a semiconductor substrate 310 and microlens 380(0). Image sensor 300 may include additional microlenses 380, such as one or more of microlenses 380(1-3) shown in FIGS. 3-6. Microlenses 380(1), 380(2), and 380(3) are directly above each pixel of respective pixel cell 224(1), 224(2), and 224(3). Microlens 380 has a material composition that may include a polymer, an inorganic material, a photoresist, silicon nitride, a resin, or any combination thereof. In embodiments, microlenses 380 are part of a microlens array 380A that includes plurality of rows and a plurality of columns of microlenses 380.

Herein, a number in parenthesis following a reference number is an instance of the referent of the reference number. For example, each of microlenses 380(0-3) is an instance of microlens 380. Statements describing features and/or properties of a referent using a reference number lacking parenthesis, e.g., “microlens 380” may apply to one or more instances of the referent with parenthesis, e.g., one or more of microlenses 380(0-3). Also, the letter k in parenthesis following a reference number is the k^{th} instance of the referent of the reference number. For example, the statement “in embodiments, microlens 380(k) is above pixel cell 224(k)” is true for each of k=0, k=1, k=2, and k=3. Similarly, statements describing a referent using a reference number having parenthesis, e.g., microlens 380(0), may apply to any other instance of the referent, e.g., one or more of microlens 380(1), 380(2), and 380(3).

Semiconductor substrate 310 includes pixel array 220A. Microlens array 380A is disposed on a pixel array (e.g., pixel array 220A). Microlens 380 is disposed on semiconductor substrate 310 and is directly above pixel cell 224 of pixel array 220A. Along axis A3, each pixel 220 of pixel cell 224(k) is directly beneath a respective part of toric microlens 380(k).

Image sensor 300 may include a color filter 361 between microlens 380 and each pixel 220 of pixel cell 224. For example, for one or more values of k, image sensor 300 may include a color filter 361(k) between microlens 380(k) and pixel cell 224(k). Each pixel 220 has a photodiode 222 such that each cell 224 includes four photodiodes 222.

Each photodiode 220 may be a photosensitive element (e.g., a pinned photodiode) comprising one or more doped regions of the semiconductor substrate 310 that collectively and/or in combination with the semiconductor substrate form a PN junction within the semiconductor substrate 310 capable of photogenerating charge carriers responsive to an intensity of light incident upon the respective photodiode 222 directed by respective microlens 380(k). Adjacent photodiode 220 may be electrically and/or optically isolated from each other, for example by an isolation structure (not illustrated).

Color filter 361(k) is aligned above each photodiode 222 of pixel 224(k). A color filter 361 may be one of a red filter, blue filter, green filter, clear filter, and an infrared color filter. In various embodiments, each of color filters 361(0) and 361(3) is a green color filter. In such embodiments, one of color filters 361(1) and 361(2) is a red color filter while the other is a blue color filter. Color filters 361 may form a color filter array 360, which may be arranged based on Bayer pattern, thus may be referred as a Bayer array.

In embodiments, a metal grid or a composite metal grid (e.g., a vertical stack of low refractive-index material and metal structure) may be disposed to define apertures optically aligned with each pixel 220 and separating adjacent color filter 361(k). For example, FIGS. 3-5 depict a grid element 368 between adjacent color filters 361. In some embodiments, the low refractive-index material may be encapsulating the metal structure to form the grid element 368 i.e., the low refractive-index material is disposed on and surrounds the metal structure for cross-talk reduction and quantum efficient improvement.

Microlens 380 has an optical axis 388, which may be parallel to axis A3. In embodiments, at least one of cross-sectional planes 3-3′, 4-4′, and 5-5′ includes, and is parallel to, optical axis 388. Along optical axis 388, a combined or overall thickness 386 of microlens 380 and layer 370 with respect to a top surface of color filter 361 that is substantially identical in each of cross-sectional planes 3-3′, 4-4′, and 5-5′. Semiconductor substrate 310 has a top substrate surface 319, which may be perpendicular to at least one of cross-sectional planes 3-3′, 4-4′, and 5-5′.

Microlens 380 has a surface 389 and may be a toric microlens. FIGS. 3A, 3B, 4A, 4B, 5A, and 5B depict radii of curvature 381, 481, and 581 of surface 389. Herein, and unless otherwise noted, the term “radius” denotes a radius of curvature, such that radii of curvature 381, 481, and 581 are referred to as radii 381, 481, and 581, respectively.

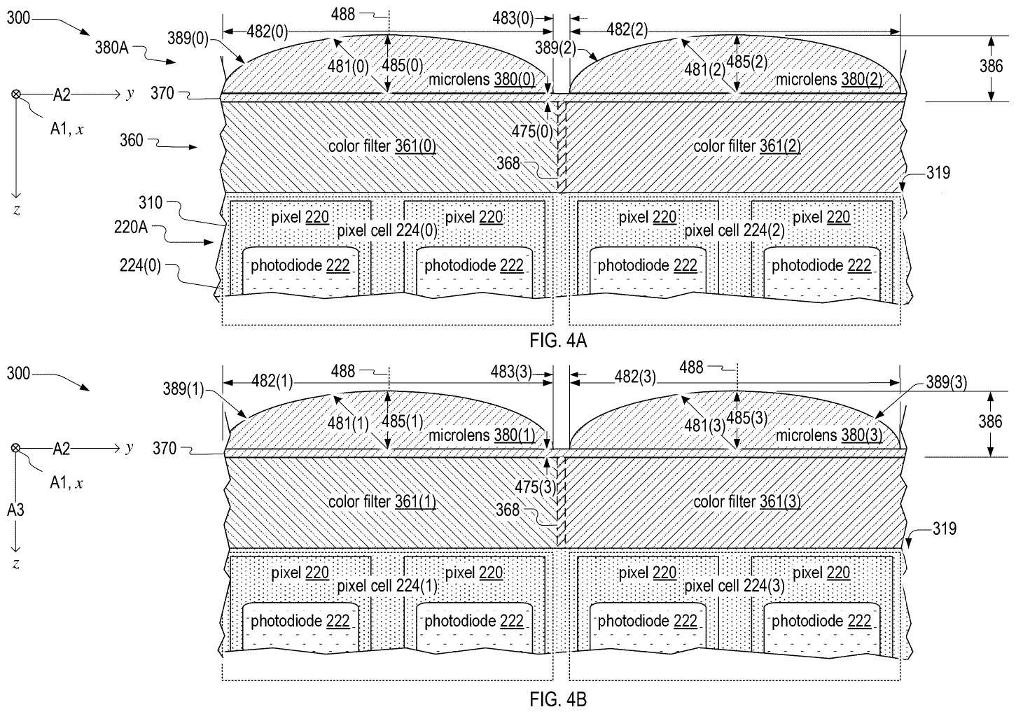

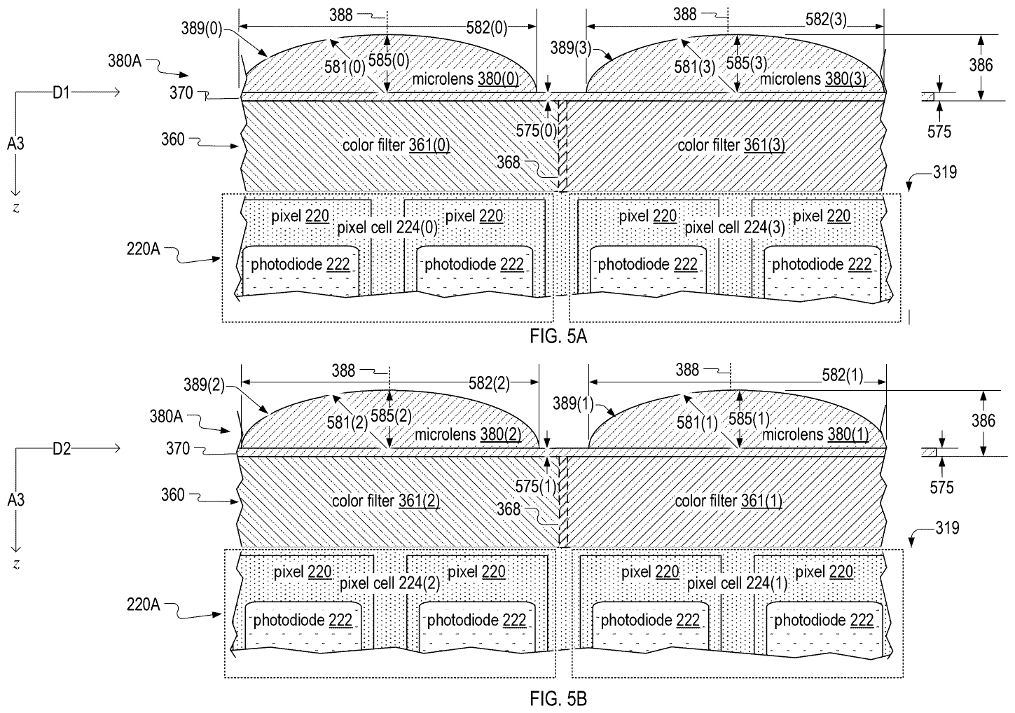

Surfaces 389(0) and 389(1) have respective radii 381(0) and 381(1) in cross-sectional plane 3a-3a′, as shown in FIG. 3A. Surfaces 389(2) and 389(3) have respective radii 381(2) and 381(3) in cross-sectional plane 3b-3b′, as shown in FIG. 3B. Surfaces 389(0) and 389(2) have respective radii 481(0) and 481(2) in cross-sectional plane 4a-4a′, as shown in FIG. 4A. Surfaces 389(1) and 389(3) have respective radii 481(1) and 481(3) in cross-sectional plane 4b-4b′, as shown in FIG. 4B. Surfaces 389(0) and 389(3) have respective radii 581(0) and 581(3) in cross-sectional plane 5a-5a′, as shown in FIG. 5A. Surfaces 389(2) and 389(1) have respective radii 581(2) and 581(1) in cross-sectional plane 5b-5b′, as shown in FIG. 5B.

Herein, a microlens 380 qualifies as a “toric microlens,” or equivalently having a toric surface, when at least two of its radii 381, 481, and 581 are not equal. For example, radius 381 may differ from one or more of radius 481 and 581. For example, microlens 380(0) has first surface 389(0) with radius 381(0) and second surface 489(0) with radius 489(0), wherein radius 381(0) and radius 481(0) are different e.g., radius 381(0) may be less than radius 481(0). For another example, microlens 380(1) has first surface 389(1) with radius 381(1) and second surface 489(1) with radius 489(1), wherein radius 381(1) and radius 481(1) are different e.g., radius 381(1) may be less than radius 481(1), as shown in FIGS. 3A and 4A.

Herein, a microlens 380 qualifies as a “symmetric microlens” when at least two of its radii 381, 481, and 581 are substantially equal or identical. For example, microlens 380(1) is symmetric when radii 381(0) and 481(0) of surface 389(0) are substantially equal. Surface 389 may be (i) either spherical or aspherical in any of cross-sectional planes 3-3′, 4-4′, and 4-4′.

Microlenses 380(0) and 380(1) have respective surface sags 385(0) and 385(1) in cross-sectional plane 3a-3a′, as shown in FIG. 3A. Microlenses 380(2) and 380(3) have respective surface sags 385(2) and 385(3) in cross-sectional plane 3b-3b′, as shown in FIG. 3B. Cross-sectional planes 3a-3a′ and 3b-3b′ are parallel to the A1-A3 plane. Microlenses 380(0) and 380(2) have respective surface sags 485(0) and 485(2) in cross-sectional plane 4a-4a′, as shown in FIG. 4A. Microlenses 380(1) and 380(3) have respective surface sags 485(1) and 485(3) in cross-sectional plane 4b-4b′, as shown in FIG. 4B. Cross-sectional planes 4a-4a′ and 4b-4b′ are parallel to the A2-A3 plane.

Microlenses 380(0) and 380(3) have respective heights 585(0) and 585(3) in cross-sectional plane 5a-5a′, as shown in FIG. 5A. Cross-sectional plane 5a-5a′ is parallel to the D1-A3 plane. Microlenses 380(2) and 380(1) have respective height 585(2) and 585(1) in cross-sectional plane 5b-5b′, as shown in FIG. 5B. Cross-sectional plane 5b-5b′ is parallel to the D2-A3 plane. Surface sag 385(k) may differ from one or more of surface sags 485(k). One or more of surface sags 385(k) and 485(k) may also differ from one of heights 585(k).

Surface sag enables the respective microlens to have a surface with corresponding curvature and radius, and is used herein in the disclosure referring to i) a height of a microlens that may be a difference between a maximum point of the microlens and a minimum point of the microlens along a respective direction, and 2) a vertical height that is measured with respect to a surface plane (e.g., a top surface of layer 370) In embodiments, surface sag and radius of curvature of microlens 380 are related by equations (1) and (2).

$${R}_{x} = ( {S}_{x}^{2} + {P}_{x}^{2} / 4 ) / ( 2 {S}_{x} ) \qquad ( 1 )$$

$${R}_{y} = ( {S}_{y}^{2} + {P}_{y}^{2} / 4 ) / ( 2 {S}_{y} ) \qquad ( 2 )$$

In equations (1) and (2), Rₓ and Sₓ are the radius of curvature and sag, respectively, in cross-sectional plane 3-3′ (FIGS. 3A, 3B), R_{y} and S_{y} are the radius of curvature and sag, respectively, in cross-sectional plane 4-4′ (FIGS. 4A, 5B), Pₓ is the horizontal pixel pitch, and P_{y} is the vertical pixel pitch. Pixel pitches Pₓ and P_{y} may be equal.

Each of surface sags 585(0), 585(1), 585(2), and 585(3) may further related to pixel pitches Pₓ and P_{y} by equation (3)

$$D = \frac{α}{2} \cdot \sqrt{{P}_{x}^{2} + {P}_{y}^{2}} \qquad ( 3 )$$

Coefficient α may be greater than or equal to 0.707 and less than or equal to 1. In equation (3), D refers to a height of a respective microlens measured along a diagonal direction i.e., each of heights 585(0), 585(1), 585(2), and 585(3). In some embodiments, D refers to a maximum height of a respective microlens.

Thickness 386 may exceed at least one of surface sags 385, 485, and 585. For example, image sensor 300 may include a layer 370 disposed between respective microlens 380(k) and color filter 361(k), and surface 389 of respective microlens 380(k) may be a protrusion of a layer 370. Accordingly, layer 370 and microlens 380 may have the same material composition. In such embodiments, microlens 380 is part of layer 370, and may be monolithically formed with layer 370. In embodiments, layer 370 may be formed of a polymer, an inorganic material, a photoresist, silicon nitride, a resin, or any combination thereof.

Between adjacent microlenses 380, layer 370 has respective layer thicknesses 375, 475, and 575 in cross-sectional planes 3-3′, 4-4′, and 5-5′. Accordingly, in embodiments of microlens 380, each of the following quantities equals thickness 386: layer thickness 375 plus surface sag 385, layer thickness 475 plus surface sag 485, and layer thickness 575 plus height 585.

In various of embodiments, layer 370 has a thickness 375(0) between microlenses 380(0) and 380(1) and a thickness 375(3) between microlenses 380(2) and 380(3) along A3 direction, as shown in FIGS. 3A and 3B, respectively. Layer 370 has a layer thickness 475(0) between microlenses 380(0) and 380(2) and a layer thickness 475(3) between microlenses 380(1) and 380(3) along A3 direction, as shown in FIGS. 4A and 4B, respectively. Layer 370 has a layer thickness 575(0) between microlenses 380(0) and 380(3) and a layer thickness 575(1) between microlenses 380(1) and 380(2) along A3 direction, as shown in FIGS. 5A and 5B, respectively. Layer thickness 375(0) may differ from at least one of layer thicknesses 475(0) and 575(0). Layer thickness 575(0) may differ from each of layer thicknesses 375(0) and 475(0). In some embodiments, layer thickness 475(0) of layer 370 is greater than layer thickness 375(0), and layer thickness 475(3) of layer 370 is greater than layer thickness 375(3). In the same or different embodiments, at least one of layer thickness 375(0) and 475(0) is greater than layer thickness 575(0) and at least one of layer thickness 375(3) and 475(3) is greater than layer thickness 575(3).

In embodiments, a larger surface sag of microlens 380 in a cross-sectional plane results in a smaller radius of curvature in the cross-sectional plane, as a larger surface sag results from more material having been removed (e.g., etched) from a planar film to form microlens 380 having narrower focus area. For example, in such embodiments, when surface sag 385 exceeds surface sag 485, radius 381 is less than radius 481, layer thickness 475(0) of layer 370 is greater than layer thickness 375(0), and layer thickness 475(3) is greater than layer thickness 375(3), resulting steep curvature, which provides smaller focused spots along x-direction.

In embodiments, height 585 along A3 direction exceeds both of surface sag 385 and 485. In a first instance of such an embodiment, surface sag 485 exceeds surface sag 385, a ratio r_{x/D} of the surface sag 385 to height 585 is between 0.5 and 1.0, and a ratio r_{y/D} of the surface sag 485 to height 585 is between 0.3 and 0.7. Moreover, in such embodiment, the ratio r_{x/D} of the surface sag 385 to height 585 is greater than the ratio r_{y/D} of the surface sag 485 to height 585. In a second instance of such an embodiment, surface sag 385 exceeds surface sag 485, a ratio of the surface sag 385 to height 585 is between 0.3 and 0.7, and a ratio of the surface sag 485 to height 585 is between 0.5 and 1.0. Moreover, in second instance, the ratio r_{x/D} of the surface sag 385 to height 585 is less than the ratio r_{y/D} of the surface sag 485 to height 585. This second instance may be viewed as the first instance rotated by ninety degrees in the A1-A2 plane. Such configuration allows the respective microlens 380 to form a smaller or narrower focused area along axis A1 for higher PD selectively while larger focused area along axis A2 improving QPD sensitivity.

Microlens 380 has a horizontal width 382 parallel to axis A1 and a vertical width 482 parallel to axis A2. In embodiments, either: (i) radius 381 exceeds radius 481 and horizontal width 382 exceeds vertical width 482 or (ii) radius 481 exceeds radius 381 and vertical width 482 exceeds horizontal width 382.

In embodiments, each of microlens 380(0) is adjacent to an additional toric microlens, such that at least one of microlenses 380(1-3) is a toric microlens. For example, each of microlenses 380(0) and 380(3) may be a toric microlens while at least one microlenses 380(1) and 380(2) is also a toric microlens.

Microlens 380(0) and the additional toric microlens may have the same orientation or have orthogonal rotational orientations in the A1-A2 plane. In the following description, the radii 381(k≠0), 481(k≠0), and 581(k≠0) denote the radii of curvature of the at least one of microlenses 380(1), 380(2), and 380(3). Examples of microlens 380(0) and the additional microlens having the same orientation include when either (i) radius 481(0) exceeds radius 381(0) and radius 481(k≠0) exceeds radius 381(k≠0) or (ii) radius 381(0) exceeds radius 481(0) and radius 381(k≠0) exceeds radius 481(k≠0). Examples of microlens 380(0) and the additional microlens having the orthogonal orientation include when either (i) radius 481(0) exceeds radius 381(0) and radius 381(k≠0) exceeds radius 481(k≠0) or (ii) radius 381(0) exceeds radius 481(0) and radius 481(k≠0) exceeds radius 381(k≠0).

Microlenses 380(0) and 380(1) are separated by a horizontal distance 383(0) along axis A1, as shown in FIG. 3A. Microlenses 380(0) and 380(2) are separated by a vertical distance 483(0) along axis A2, as shown in FIG. 4A. In embodiments, horizontal distance 383(0) exceeds vertical distance 483(0), e.g., when at least one of (i) radius 381(0) is less than radius 481(0) and (ii) radius 381(1) is less than radius 481(1). In other embodiments, horizontal distance 383(0) is less than vertical distance 483(0), e.g., when at least one of (i) radius 381(0) exceeds radius 481(0) and (ii) radius 381(1) exceeds radius 481(1). Each of the horizontal distance 383(0) and vertical distance 483(0) may be less than a separation between microlenses 380(0) and 380(3) along axis D1.

Microlenses 380(2) and 380(3) are separated by a horizontal distance 383(3) along axis A1, as shown in FIGS. 3B and 6. Microlenses 380(1) and 380(3) are separated by a vertical distance 483(3) along axis A2, as shown in FIGS. 4B and 6. In embodiments, horizontal distance 383(3) exceeds vertical distance 483(3), e.g., when at least one of (i) radius 381(2) is less than radius 481(2) and (ii) radius 381(3) is less than radius 481(3). In other embodiments, horizontal distance 383(3) is less than vertical distance 483(3), e.g., when at least one of (i) radius 381(2) exceeds radius 481(2) and (ii) radius 381(3) exceeds radius 481(3). In embodiments, each horizontal distance 383 exceeds each vertical distance 483. In other embodiments, each horizontal distance 383 is less than each vertical distance 483. Each of the horizontal distance 383(3) and vertical distance 483(3) may be less than a separation between microlenses 380(2) and 380(1) along axis D2.

In embodiments, each horizontal distance between pairs of horizontally adjacent microlenses 380 is substantially equal and each vertical distance between pairs of vertically adjacent microlenses 380 is substantially equal. In such embodiments, all horizontal distances 383 are equal and all vertical distances 483 are equal, and horizontal distance 383 differs from vertical distance 483. Horizontal distance 383 may either exceed vertical distance 483 or be less than vertical distance 483.

FIG. 6 shows microlenses 380(0-3) above a respective pixel cells 224(0-3), which are arranged as a two-by-two array. In embodiments, pixel cells 224(0-3) may represent a minimum repeating array unit and a plurality of pixel cells 224(0-3) is arranged into rows and column to form pixel array 220A.

In some embodiments, two of microlenses 380(0-3) are toric microlenses and the remaining two of microlenses 380(0-3) are symmetric about their respective optical axis. For example, each of microlenses 380(0) and 380(3) may be a toric microlens while each of microlenses 380(1) and 380(2) may be symmetric microlens.

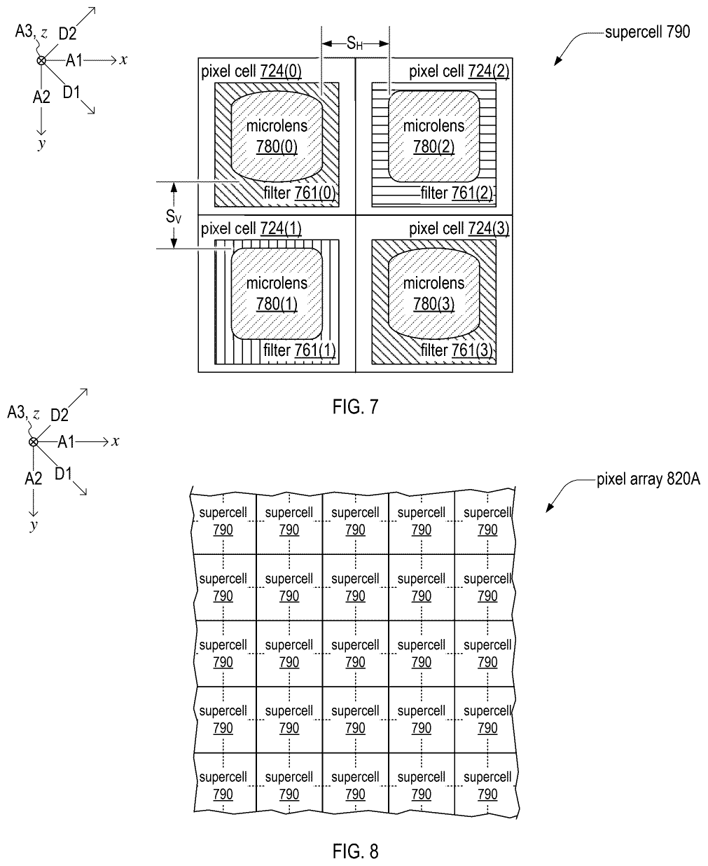

FIG. 7 is a plan view of a two-by-two array of pixel cells 724(0-3) that form a supercell 790. The shape of microlens 780(k) as shown in FIG. 7 is for illustration differentiating toric and symmetric microlens, and should not be interpret as the exact orientation nor the size of microlens 780(k). For example, microlens 780(0) and the additional toric microlens 780(1) may have the same orientation or have orthogonal rotational orientations in the A1-A2 plane.

FIG. 8 is a plan view of a pixel array 820A, which is an example of pixel array 220A, FIG. 2. Pixel array 820A includes an array of supercells 790. FIGS. 7 and 8 are best viewed together in the following description.

Pixel cells 724(0-3) are respective examples of a pixel cells 224(0-3). Each pixel cell 724 includes a color filter 761(k) and a microlens 780(k), which are respective examples of color filter 361(k) and 380(k). Microlens 780(k) is configured to direct incident light through respective color filter 761(k) and to pixel cells 724(k).

Pixel cells 724(0) and 724(3) include respective color filters 761(0) and 761(3) and a respective microlenses 780(0) and 780(3). Pixel cells 724(1) and 724(2) include respective color filters 761(1) and 761(2) and a respective microlenses 780(1) and 780(2).

In embodiments, supercell 790 has at least one of the following features:
Feature 1: Each of color filters 761(0) and 761(3) is a green color filter such that pixel cell 724(0) and 724(3) may be referred to as green color pixel cells.
Feature 2: Color filter 761(1) is a red color filter such that pixel cell 724(1) may be referred to as red color pixel cell.
Feature 3: Color filter 761(2) is a blue color filter such that pixel cell 724(2) may be referred to as blue color pixel cell.
Feature 4: Each of microlenses 780(1) and 780(2) is symmetric microlens.
Feature 5: Each of microlenses 780(0) and 780(3) is a toric microlens having the same orientation. Each of microlenses 780(0) and 780(3) may be examples of microlens 380.

In some embodiments, supercell 790 has features 1-3, pixel cells 724(0) and 724(3) may be referred to as a “Gb” (first green) pixel cell and a “Gr” (second green) pixel cell, respectively, as within supercell 790. Pixel cell 724(0) is vertically adjacent (along axis A2) to a pixel cell 724(1) while pixel cell 724(0) is horizontally adjacent to a pixel cell 724(2. Pixel cell 724(3) is horizontally adjacent (along axis A2) to a pixel cell 724(1) while vertically adjacent to a pixel cell 724(2).

In such embodiments, having a toric microlens on each of pixel cells 724 of supercell 790 may cause uneven light distribution along in directions along axis A1 and A2, which increases differences in pixel signals of produced by Gr pixel cell 724(0) and Gb pixel cell 724(3), which degrades image quality. When supercell 790 has features 1-3, a technical benefit of features 4 and 5 is increased sensitivity uniformity across pixel array 820A, which can mitigate or reduce differences between the Gr pixel cell and the Gb pixel cell to an acceptable value, thus improving overall image quality and providing desired phase detection selectivity that benefits phase detection auto-focus operation.

Orientation of toric microlenses is discussed above, where microlens 780(0) is an example of microlens 380(0) and microlens 780(3) is an example of the additional microlens. In some embodiments, microlenses 780(0) and 780(3) having the same orientation means that both (i) the radius of curvature of microlens 780(0) in the A1-A3 plane exceeds the radius of curvature of microlenses 780(0) in the A2-A3 plane and (ii) the radius of curvature of microlens 780(3) in the A1-A3 plane exceeds the radius of curvature of microlenses 780(3) in the A2-A3 plane. In other embodiments, microlenses 780(0) and 780(3) having the same orientation means that both (i) the radius of curvature of microlens 780(0) in the A1-A3 plane is less than the radius of curvature of microlenses 780(0) in the A2-A3 plane and (ii) the radius of curvature of microlens 780(3) in the A1-A3 plane is less than the radius of curvature of microlenses 780(3) in the A2-A3 plane.

In illustrated embodiments, a horizontal distance S_{H} between microlens 780(0) and microlens 780(2) along axis A1 differs from a vertical distance S_{V} between microlenses 780(0) and 780(1) along axis A2. In some embodiments, depending on the orientation of microlens 780(0), the horizontal distance S_{H} between microlens 780(0) and microlens 780(2) along axis A1 exceeds the vertical distance S_{V} between microlenses 780(0) and 780(1) along axis A2. In other embodiments, the horizontal distance S_{H} between microlens 780(0) and microlens 780(2) along axis A1 is less than the vertical distance S_{V} between microlenses 780(0) and 780(2) along axis A2.

Orientation of symmetric microlenses is discussed above, where microlens 780(1) and microlens 780(2) may be examples of the additional microlenses. In embodiments, microlenses 780(1) and 780(2) have the same orientation with substantially same radii in all directions i.e., (i) the radius of curvature of microlens 780(1) in the A1-A3 plane is substantially equal to the radius of curvature of microlenses 780(2) in the A2-A3 plane and (ii) the radius of curvature of microlens 780(1) in the A1-A3 plane is substantially equal to the radius of curvature of microlenses 780(2) in the A2-A3 plane. Microlens 780(1) and microlens 780(2) may be of spherical-shaped in any of cross-sectional planes such as cross-sectional planes 3-3′, 4-4′, and 4-4′.

### Combinations of Features

Features described above as well as those claimed below may be combined in various ways without departing from the scope hereof. The following enumerated examples illustrate some possible, non-limiting combinations.

Embodiment 1. An image sensor comprising: a semiconductor substrate including a pixel array having a plurality pixel cells arranged into a plurality of rows and a plurality of columns, a pixel cell of the pixel array including a two-by-two sub-array of pixels of the pixel array; and a plurality of toric microlenses disposed on the semiconductor substrate, arranged into a plurality of microlens rows and a plurality of microlens columns, each toric microlens being directly above a corresponding pixel cell of the pixel array; each toric microlens having a horizontal width, and a vertical width that differs from the horizontal width, such that a vertical separation between adjacent microlenses in adjacent microlens rows differs from a horizontal separation between adjacent microlenses in adjacent microlens columns; the horizontal width being in a direction parallel to each of the plurality of rows; the vertical width being in a direction parallel to each of the plurality of columns.

Embodiment 2. An image sensor comprising: a semiconductor substrate including a pixel array having a plurality of rows of pixels and a plurality of columns of pixels, a pixel cell of the pixel array including a two-by-two sub-array of pixels of the pixel array; and a toric microlens disposed on the semiconductor substrate and directly above a corresponding pixel cell of the pixel array.

Embodiment 3. The image sensor of either one of embodiments 1 or 2, the pixel array being wider in a horizontal direction parallel to each of the plurality of rows than in a vertical direction parallel to each of the plurality of columns and perpendicular to the horizontal direction; a surface of the toric microlens having (i) a first radius of curvature in a first cross-sectional plane parallel to the horizontal direction and perpendicular to a top substrate-surface of the semiconductor substrate; and (ii) a second radius of curvature in a second cross-sectional plane parallel to the vertical direction and perpendicular to the top substrate-surface, the first radius differing from the second radius, and each of the first cross-sectional plane and the second cross-sectional plane including the optical axis of the toric microlens.

Embodiment 4. The image sensor of any one of embodiments 1-3, the toric microlens having a surface sag in the first cross-sectional plane; a surface sag in the second cross-sectional plane parallel to the vertical direction and perpendicular to the top substrate-surface, the surface sag differing from the surface sag; and a height in a third cross-sectional plane that is diagonally oriented with respect to the first and the second cross-sectional planes and perpendicular to the top substrate-surface, wherein the height exceeds both of the surface sag and the surface sag.

Embodiment 5. The image sensor of any one of embodiments 1-4, the surface sag exceeding the surface sag; a ratio of the surface sag to the height being between 0.5 and 1.0; and a ratio of the surface sag to the height being between 0.3 and 0.7; wherein the ratio of the surface sag to the height is larger than the ratio of the surface sag to the height.

Embodiment 6. The image sensor of either one of embodiments 4 or 5, the surface sag exceeding the surface sag; a ratio of the surface sag to the height being between 0.3 and 0.7; and a ratio of the surface sag to the height being between 0.5 and 1.0 wherein the ratio of the surface sag to the height is less than the ratio of the surface sag to the height.

Embodiment 7. The image sensor of any one of embodiments 4-6, the toric microlens having, along an optical axis thereof, an overall thickness that (i) is substantially identical in each of the first, the second, and the third cross-sectional planes and (ii) exceeds at least one of the surface sag, the surface sag, and the height, the optical axis being oriented in a depth direction perpendicular to each of the horizontal and vertical directions.

Embodiment 8. The image sensor of any one of embodiments 3-8, The toric microlens having a horizontal width in the first cross-sectional plane and a vertical width in the second cross-sectional plane, wherein either: (i) the first radius exceeds the second radius and the horizontal width exceeds the vertical width or (ii) the second radius exceeds the first radius and the vertical width exceeds the horizontal width.

Embodiment 9. The image sensor of any one of embodiments 3-9, the pixel array including a first additional pixel cell, a second additional pixel cell, and a third additional pixel cell that are respectively horizontally adjacent, vertically adjacent, and diagonally adjacent to the pixel cell, and further comprising: a first additional microlens directly above each pixel of the first additional pixel cell; a second additional microlens directly above each pixel of the second additional pixel cell; and a third additional microlens directly above each pixel of the third additional pixel cell; at least one of the first, the second, and the third additional microlens having a toric surface.

Embodiment 10. The image sensor of embodiment 9, the third additional microlens being an additional toric microlens.

Embodiment 11. The image sensor of either one of embodiments 9 or 10, a surface of the additional toric microlens having (i) a third radius of curvature in a third cross-sectional plane parallel to the first cross-sectional plane; and (ii) a fourth radius of curvature in a fourth cross-sectional plane parallel to second cross-sectional plane and differing from the third radius of curvature, each of the third cross-sectional plane and the fourth cross-sectional plane including the optical axis of the additional toric microlens.

Embodiment 12. The image sensor of embodiment 11, the toric microlens and the additional toric microlens having a same orientation resulting from either: the second radius exceeding the first radius and the fourth radius exceeding the third radius; or the first radius exceeding the second radius and the third radius exceeding the fourth radius.

Embodiment 13. The image sensor of either one of embodiments 11 or 12, the toric microlens and the additional toric microlens having a different orientations resulting from either: the second radius exceeding the first radius and the third radius exceeding the fourth radius; or the first radius exceeding the second radius and the fourth radius exceeding the third radius.

Embodiment 14. The image sensor of any one of embodiments 9-13, the third additional microlens being an additional toric microlens; at least one of the first and the second additional microlens being a symmetric microlens having (i) a third radius of curvature in a third cross-sectional plane parallel to the first cross-sectional plane; and (ii) a fourth radius of curvature in a fourth cross-sectional plane parallel to second cross-sectional plane, each of the third cross-sectional plane and the fourth cross-sectional plane including the optical axis of the additional toric microlens; and the third radius of curvature and the fourth radius of curvature being equal.

Embodiment 15. The image sensor of any one of embodiments 9-14, the third additional microlens being an additional toric microlens; at least one of the first and the second additional microlens being a toric microlens having (i) a third radius of curvature in a third cross-sectional plane parallel to the first cross-sectional plane; and (ii) a fourth radius of curvature in a fourth cross-sectional plane parallel to second cross-sectional plane, each of the third cross-sectional plane and the fourth cross-sectional plane including the optical axis of the additional toric microlens; and the third radius of curvature differing from the fourth radius of curvature.

Embodiment 16. The image sensor of any one of embodiments 9-15, along the horizontal direction, a horizontal distance between the microlens and the first additional microlens differing from a vertical distance between the microlens and the second additional microlens along the vertical direction.

Embodiment 17. The image sensor of embodiment 16, the horizontal distance exceeding the vertical distance.

Embodiment 18. The image sensor of embodiment 16, the vertical distance exceeding the horizontal distance.

Embodiment 19. The image sensor of any one of embodiments 9-18, the microlens and each of the first, the second, and the third additional microlens being a respective convex protrusion of a monolithic material layer having, in a direction perpendicular to the top substrate-surface: a first thickness, along a direction perpendicular to the top substrate-surface, between the microlens and the first additional microlens, a second thickness, along a direction perpendicular to the top substrate-surface, between the microlens and the second additional microlens, that differs from the first thickness, and a third thickness, along a direction perpendicular to the top substrate-surface, between the microlens and the third additional microlens, that differs from each of the first thickness and the second thickness.

Embodiment 20. The image sensor of any one of embodiments 9-19, the third additional microlens being a toric microlens, and further comprising: a green color-filter between the toric microlens and each pixel of the pixel cell; an additional green color-filter located (i) between the third additional microlens and each pixel of the third additional pixel cell, and (ii) diagonally adjacent to the green color-filter; a blue color-filter between the first additional pixel cell and the first additional microlens; and a red color-filter located (i) between the second additional pixel cell and the second additional microlens and (ii) diagonally adjacent to the blue color-filter; wherein each of the first additional microlens and the second additional microlens is a symmetric microlens.

Embodiment 21. The image sensor of embodiment 20, each of the first additional microlens and the second additional microlens being spherical, and each of the toric microlens and the third additional microlens being non-spherical.

Embodiment 22. A pixel cell included in an image sensor comprising: a semiconductor substrate having one or more photodiodes; a color filter disposed on the semiconductor, directly above the one or more photodiodes, and a microlens, the color filter being disposed between the microlens and the semiconductor substrate and directing an incident light toward the one or more photodiodes; wherein in the microlens having a first width in a first direction and a second width in the second direction perpendicular to the first direction, wherein either: (i) the first width exceeds the second width or (ii) the second width exceeds the first width.

Embodiment 23. The pixel cell of any one of embodiments 9-22, the toric microlens having a surface sag in the first cross-sectional plane; a surface sag in the second cross-sectional plane parallel to the vertical direction and perpendicular to the top substrate-surface, the surface sag differing from the surface sag; and a surface sag in a third cross-sectional plane that is diagonally oriented with respect to the first and the second cross-sectional planes and perpendicular to the top substrate-surface, wherein the surface sag exceeds both of the surface sag and the surface sag.

Changes may be made in the above methods and systems without departing from the scope of the present embodiments. It should thus be noted that the matter contained in the above description or shown in the accompanying drawings should be interpreted as illustrative and not in a limiting sense. Herein, and unless otherwise indicated the phrase “in embodiments” is equivalent to the phrase “in certain embodiments,” and does not refer to all embodiments.

The expression of singular or plural terms may also include the plural or singular term, respectively. In addition, unless the word “or” is expressly limited to mean only a single item exclusive from the other items of a list of two or more items, then the use of “or” in such a list is to be interpreted as including (a) any single item in the list, (b) all of the items in the list, or (c) any combination of the items in the list. Further, regarding instances of the terms “and/or” and “at least one of,” for example, in the cases of “A and/or B,” “at least one of A and B,” and “at least one of A or B,” such phrasing encompasses the selection of (i) A only, or (ii) B only, or (iii) both A and B. In the cases of “A, B, and/or C,” “at least one of A, B, and C,” and “at least one of A, B, or C,” such phrasing encompasses the selection of (i) A only, or (ii) B only, or (iii) C only, or (iv) A and B only, or (v) A and C only, or (vi) Band C only, or (vii) each of A and B and C. This may be extended for as many items as are listed.

The following claims are intended to cover all generic and specific features described herein, as well as all statements of the scope of the present method and system, which, as a matter of language, might be said to fall therebetween.

We claim:

1. An image sensor comprising:
a semiconductor substrate including a pixel array having a plurality pixel cells arranged into a plurality of rows and a plurality of columns, a pixel cell of the pixel array including a two-by-two sub-array of pixels of the pixel array; and
a plurality of toric microlenses disposed on the semiconductor substrate, arranged into a plurality of microlens rows and a plurality of microlens columns, each toric microlens being directly above a corresponding pixel cell of the pixel array;
each toric microlens having a horizontal width, and a vertical width that differs from the horizontal width, such that a vertical separation between adjacent microlenses in adjacent microlens rows differs from a horizontal separation between adjacent microlenses in adjacent microlens columns;
the horizontal width being in a direction parallel to each of the plurality of rows;
the vertical width being in a direction parallel to each of the plurality of columns.

2. An image sensor comprising:
a semiconductor substrate including a pixel array having a plurality of rows of pixels and a plurality of columns of pixels, a pixel cell of the pixel array including a two-by-two sub-array of pixels of the pixel array; and
a toric microlens disposed on the semiconductor substrate and directly above a corresponding pixel cell of the pixel array.

3. The image sensor of claim 2,
the pixel array being wider in a horizontal direction parallel to each of the plurality of rows than in a vertical direction parallel to each of the plurality of columns and perpendicular to the horizontal direction;
a surface of the toric microlens having (i) a first radius of curvature in a first cross-sectional plane parallel to the horizontal direction and perpendicular to a top substrate-surface of the semiconductor substrate; and (ii) a second radius of curvature in a second cross-sectional plane parallel to the vertical direction and perpendicular to the top substrate-surface, the first radius differing from the second radius, and
each of the first cross-sectional plane and the second cross-sectional plane including the optical axis of the toric microlens.

4. The image sensor of claim 3, the toric microlens having
a surface sag Sₓ in the first cross-sectional plane;
a surface sag S_{y} in the second cross-sectional plane parallel to the vertical direction and perpendicular to the top substrate-surface, the surface sag Sₓ differing from the surface sag S_{y}; and
a height H_{d} in a third cross-sectional plane that is diagonally oriented with respect to the first and the second cross-sectional planes and perpendicular to the top substrate-surface, wherein the height H_{d} exceeds both of the surface sag Sₓ and the surface sag S_{y}.

5. The image sensor of claim 4,
the surface sag S_{y} exceeding the surface sag Sₓ;
a ratio of the surface sag Sₓ to the height H_{d} being between 0.5 and 1.0; and
a ratio of the surface sag S_{y} to the height H_{d} being between 0.3 and 0.7;
wherein the ratio of the surface sag Sₓ to the height H_{d} is larger than the ratio of the surface sag S_{y} to the height Ha.

6. The image sensor of claim 4,
the surface sag Sₓ exceeding the surface sag S_{y};
a ratio of the surface sag Sₓ to the height H_{d} being between 0.3 and 0.7; and
a ratio of the surface sag S_{y} to the height H_{d} being between 0.5 and 1.0 wherein the ratio of the surface sag Sₓ to the height H_{d} is less than the ratio of the surface sag S_{y} to the height H_{d}.

7. The image sensor of claim 4, the toric microlens having, along an optical axis thereof, an overall thickness that (i) is substantially identical in each of the first, the second, and the third cross-sectional planes and (ii) exceeds at least one of the surface sag S_{y}, the surface sag S_{y}, and the height H_{d},
the optical axis being oriented in a depth direction perpendicular to each of the horizontal and vertical directions.

8. The image sensor of claim 3,
The toric microlens having a horizontal width Wₓ in the first cross-sectional plane and a vertical width W_{y} in the second cross-sectional plane, wherein either: (i) the first radius exceeds the second radius and the horizontal width Wₓ exceeds the vertical width W_{y} or (ii) the second radius exceeds the first radius and the vertical width W_{y} exceeds the horizontal width Wₓ.

9. The image sensor of claim 3,
the pixel array including a first additional pixel cell, a second additional pixel cell, and a third additional pixel cell that are respectively horizontally adjacent, vertically adjacent, and diagonally adjacent to the pixel cell, and further comprising:
a first additional microlens directly above each pixel of the first additional pixel cell;
a second additional microlens directly above each pixel of the second additional pixel cell; and
a third additional microlens directly above each pixel of the third additional pixel cell;
at least one of the first, the second, and the third additional microlens having a toric surface.

10. The image sensor of claim 9,
a surface of the additional toric microlens having (i) a third radius of curvature in a third cross-sectional plane parallel to the first cross-sectional plane; and (ii) a fourth radius of curvature in a fourth cross-sectional plane parallel to second cross-sectional plane and differing from the third radius of curvature,
each of the third cross-sectional plane and the fourth cross-sectional plane including the optical axis of the additional toric microlens.

11. The image sensor of claim 10, the toric microlens and the additional toric microlens having a same orientation resulting from either:
the second radius exceeding the first radius and the fourth radius exceeding the third radius; or
the first radius exceeding the second radius and the third radius exceeding the fourth radius.

12. The image sensor of claim 10, the toric microlens and the additional toric microlens having a different orientations resulting from either:
the second radius exceeding the first radius and the third radius exceeding the fourth radius; or
the first radius exceeding the second radius and the fourth radius exceeding the third radius.

13. The image sensor of claim 9,
the third additional microlens being an additional toric microlens;
at least one of the first and the second additional microlens being a symmetric microlens having (i) a third radius of curvature in a third cross-sectional plane parallel to the first cross-sectional plane; and (ii) a fourth radius of curvature in a fourth cross-sectional plane parallel to second cross-sectional plane, each of the third cross-sectional plane and the fourth cross-sectional plane including the optical axis of the additional toric microlens; and
the third radius of curvature and the fourth radius of curvature being equal.

14. The image sensor of claim 9,
the third additional microlens being an additional toric microlens;
at least one of the first and the second additional microlens being a toric microlens having (i) a third radius of curvature in a third cross-sectional plane parallel to the first cross-sectional plane; and (ii) a fourth radius of curvature in a fourth cross-sectional plane parallel to second cross-sectional plane, each of the third cross-sectional plane and the fourth cross-sectional plane including the optical axis of the additional toric microlens; and
the third radius of curvature differing from the fourth radius of curvature.

15. The image sensor of claim 9,
along the horizontal direction, a horizontal distance between the microlens and the first additional microlens differing from a vertical distance between the microlens and the second additional microlens along the vertical direction.

16. The image sensor of claim 15, wherein either (i) the horizontal distance exceeds the vertical distance or (ii) the vertical distance exceeds the horizontal distance.

17. The image sensor of claim 9, the microlens and each of the first, the second, and the third additional microlens being a respective convex protrusion of a monolithic material layer having, in a direction perpendicular to the top substrate-surface:
a first thickness, along a direction perpendicular to the top substrate-surface, between the microlens and the first additional microlens,
a second thickness, along a direction perpendicular to the top substrate-surface, between the microlens and the second additional microlens, that differs from the first thickness, and
a third thickness, along a direction perpendicular to the top substrate-surface, between the microlens and the third additional microlens, that differs from each of the first thickness and the second thickness.

18. The image sensor of claim 9, the third additional microlens being a toric microlens, and further comprising:
a green color-filter between the toric microlens and each pixel of the pixel cell;
an additional green color-filter located (i) between the third additional microlens and each pixel of the third additional pixel cell, and (ii) diagonally adjacent to the green color-filter;
a blue color-filter between the first additional pixel cell and the first additional microlens; and
a red color-filter located (i) between the second additional pixel cell and the second additional microlens and (ii) diagonally adjacent to the blue color-filter;
wherein each of the first additional microlens and the second additional microlens is a symmetric microlens.

19. The image sensor of claim 18, each of the first additional microlens and the second additional microlens being spherical, and each of the toric microlens and the third additional microlens being non-spherical.

20. A pixel cell included in an image sensor comprising:
a semiconductor substrate having one or more photodiodes;
a color filter disposed on the semiconductor, directly above the one or more photodiodes, and
a microlens, the color filter being disposed between the microlens and the semiconductor substrate and directing an incident light toward the one or more photodiodes;
wherein in the microlens having a first width Wₓ in a first direction and a second width W_{y} in the second direction perpendicular to the first direction, wherein either: (i) the first width Wₓ exceeds the second width W_{y} or (ii) the second width W_{y} exceeds the first width Wₓ.

21. The pixel cell of claim 9, the toric microlens having
a surface sag Sₓ in the first cross-sectional plane;
a surface sag S_{y} in the second cross-sectional plane parallel to the vertical direction and perpendicular to the top substrate-surface, the surface sag Sₓ differing from the surface sag S_{y}; and
a surface sag S_{d} in a third cross-sectional plane that is diagonally oriented with respect to the first and the second cross-sectional planes and perpendicular to the top substrate-surface, wherein the surface sag S_{d} exceeds both of the surface sag Sₓ and the surface sag S_{y}.
